(19) United States
(12) Patent Application Publication
(10) Pub. No.: US 2002/0146887 A1
(43) Pub. Date: Oct. 10, 2002

(54) Method for forming magnetoresistive random access memory with magnetic tunnelling junction

(76) Inventors: Chih-Cheng Liu, Taipei (TW); Der-Yuan Wu, Hsin-Chu City (TW)

Correspondence Address: Powell, Goldstein, Frazer & Murphy, LLP, Suite 600, 1001 Pennsylvania Avenue, Washington, DC, 20004, US

(21) Appl. No.: 09/828,386

(22) Filed: Apr. 6, 2001

(51) Int. Cl. H01L 39/00

(52) U.S. Cl. 438/300; 257/30

(57) ABSTRACT

First of all, a semiconductor substrate is provided. On the semiconductor substrate, a word line is formed and covered with a insulating layer. Next, forming a connected device in the insulating layer to connect with the first conducting line layer. In order, a pinned layer is then deposited along the first insulating layer and the connected device. On top of the pinned layer, an insulating tunnel barrier layer is formed. Then a free layer is deposited on the insulating tunnel barrier layer. There is a single large MTJ that covers the entire surface of the first insulating layer on the conducting line layer. This large MTJ is then patterned into a small MTJ by etching process and through the free layer to the surface of the insulating tunnel barrier layer. Subsequently, the small MTJ are then covered with a second insulating layer. Afterward, opening a contact hole in the second insulating layer to the top of the small MTJ. Finally, a second conducting line layer is then formed on top of the structure to contact the free layer in the small MTJ.

### BACKGROUND OF THE INVENTION

1. Field of the Invention

The present invention relates generally to a method for forming a magnetoresistance random access memory (MRAM , and more particularly to a method for forming magnetoresistance memory random access memory with magnetic tunnel junction (MTJ)

2. Description of the Prior Art

As semiconductor devices become highly integrated, the area occupied of the chip has to be maintained or more less, so as to reduce the unit cost of the circuit. For corresponding with the development of the high technology industry in the future, there is only one method to achieve this objective, that is, the area occupied by the devices shrinks, as well as the design rule. With advances in the semiconductor technology, the dimensions of the integrated circuit (IC) devices have been shrunk to the deep sub-micron range. As the semiconductor device continuously shrinks to deep sub-micron region, some problems are incurred due to the process of scaling down.

There are many types of memories in the VLSI arena. Recently, magnetoresistive random access memory (MRAM) cells suitable for fabrication using current integrated circuit manufacturing processes have been developed for use as non-volatile storage elements. Magnetoresistive random access memory (MRAM ) is based on the integration of Silicon CMOS with magnetic memory elements. Magnetoresistive random access memory (MRAM) is nonvolatile and has unlimited read and write endurance. Unlike DRAM, magnetic memory cells that store information as the orientation of magnetization of a ferromagnetic region can hold stored information for long periods of time, and are thus nonvolatile. Certain types of magnetic memory cells that use the magnetic state to alter the electrical resistance of the materials near the ferromagnetic region are collectively known as magnetoresistive (MR) memory cells. An array of magnetic memory cells is often called magnetic RAM or MRAM.

Recent advances in magnetic tunnel junction (MTJ ) materials give magnetoresistive random access memory the potential for high speed, low operating voltage, and high density. In general, the magnetoresistive random access memory devices of the Magnetic Tunnel Junction (MTJ) type include a multi-layer resistor element comprised of suitable magnetic materials which change its resistance to the flow of electrical current depending upon the direction of magnetic polarization of the layers. In a magnetic tunnel junction, two ferromagnetic layers are separated by an insulating tunnel barrier and the magnetoresistance results from the spin-polarized tunneling of conduction electrons between the two ferromagnetic layers. The tunneling current depends on the relative orientation of the magnetic moments of the two ferromagnetic layers.

In the case of MTJ-based magnetoresistive random access memory, the resistance of the cell is large and the sense currents are small (μA range). It is therefore viable to use a minimum sized active device (transistor or diode ) as the isolation device in conjunction with a magnetic tunnel junction spin valve element to define the cell of magnetoresistive random access memory. The cell area in this architecture can be defined by the larger of the active device or the magnetic tunnel junction cell. The magnetic tunnel junction spin valve uses the direction of polarization of the free layer for information storage. The resistance of the memory bit is either low or high dependent on the relative polarization, parallel or anti-parallel of the free layer with respect to the pinned layer. Uniformity of the MR ratio and the absolute resistance of the cell are critical in this architecture, since the absolute value of the magnetic tunnel junction resistance is compared with a reference cell during read mode. If the active device resistances in a block of a memory show a large resistance variation, a signal error can occur when they are compared with a reference cell.

The magnetoresistive random access memory array of conventional magnetoresistive memory cells is shown in FIG. 1A. The array includes a set of electrically conductive traces that function as parallel word lines 110A, 110B, and 110C in a horizontal plane, and a set of electrically conductive traces that function as parallel bit lines 120A, 120B, and 120C in another horizontal plane. The bit lines are oriented in a different direction, preferably at right angles to the word lines, so that the two sets of lines intersect when viewed from above. A memory cell, such as typical memory cell 130 shown in detail in FIG. 1A, is located at each crossing point of the word lines 110A, 110B, and 110C and bit lines 120A, 120B, and 120C in the intersection region vertically spaced between the lines. The memory cell 130 is arranged in a vertical stack that includes a magnetic tunnel junction (MTJ) 140, as shown in FIG. 1B. The magnetic tunnel junction (MTJ) 140 comprises a vertical stack of a pinned layer 150 having a non-variational direction of magnetization, a free layer 160 having a variational direction of magnetization and a tunnel barrier layer 170 between the pinned layer 150 and the free layer 160.

During operation of the array, current flows in a vertical direction through the cell 130. The vertical current path through the memory cell 130 permits the memory cell 130 to occupy a very small surface area. Contact to the word lines, the magnetic tunnel junction 140, and the contact to the bit line all occupy the same area. Nevertheless, some of the issues result from this traditional structure. When the scale of cell becomes more small, the magnetic line of force of the cell is more confused. Moreover, the process for forming the cell is hard to etch the sandwich structure without edge defect, and that etch aspect ratio is higher. On the other hand, the pinned layer edge is also easy to form the larger stray field. Furthermore, the magnetic field of the conventional cell is hard to be determined due to the weak signal from the resistance.

In accordance with the above description, a new and improved method for forming the cell of the magnetoresistive random access memory is therefore necessary, so as to raise the yield and quality of the follow-up process.

### SUMMARY OF THE INVENTION

In accordance with the present invention, a method is provided for fabricating the magnetoresistive random access memory with the magnetic tunnel junction that substantially overcomes drawbacks of above mentioned problems arised from the conventional methods.

Accordingly, it is a main object of the present-invention to provide a method for fabricating the magnetoresistive random access memory. This invention can form a novel structure of the magnetic tunnel junction to substitute for conventional structure, so as to obtain a good magnetiresistance performance. Hence, the present invention is appropriate for deep sub-micron technology to provide the semiconductor devices.

Another object of the present invention is to provide a method for forming a magnetic tunnel junction of the magnetoresistive random access memory. The present invention can form a larger area pinned layer in the magnetic tunnel junction, so as to avoid the stray field of the pinned layer edge and prevent the edge defect of the sandwich structure during the etching process. Moreover, this invention can get an etching stop layer by forming a larger area pinned layer to decrease the complex of process. On the other hand, the magnetic field of the present cell is easy to be determined due to the stronger signal from the resistance. Accordingly, this invention can provide a magnetoresistive random access memory that has a good magnetiresistance performance to increase yield and quality of the process and, hence, decrease cost. Therefore, the present invention can correspond to economic effect.

In accordance with the present invention, a new method for forming a magnetoresistive random access memory is disclosed. First of all, a semiconductor substrate is provided. On the semiconductor substrate, a first conducting line layer is formed and covered with a first insulating layer. Next, forming a connected device in the first insulating layer to connect with the first conducting line layer. Then the series of layers which make up the magnetic tunnel junction are deposited by magnetron sputter deposition uniformly on the surface which is held near ambient temperature. In order, a pinned layer is deposited along the first insulating layer and the connected device. On top of the pinned layer, an insulating tunnel barrier layer is formed. Then a free layer is deposited on the insulating tunnel barrier layer. There is a single large MTJ that covers the entire surface of the first insulating layer on the conducting line layer. This large MTJ is then patterned into a small MTJ by etching process and through the free layer to the surface of the insulating tunnel barrier layer. Subsequently, the small MTJ are then covered with a second insulating layer. Afterward, state-of-the-art silicon VLSI processes are then used to open a contact hole in the second insulating layer to the top of the small MTJ. Finally, a second conducting line layer is then formed on top of the structure to contact the free layer in the small MTJ.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A shows cross-sectional views illustrative of the structure of the conventional magnetoresistance random access memory having conventional magnetic tunnel junction;

FIG. 1B shows cross-sectional views illustrative of the structure of the conventional magnetic tunnel junction;

FIG. 2A to FIG. 2D show cross-sectional views illustrative of various stages for forming a magnetoresistance random access memory having a magnetic tunnel junction in accordance with the embodiment of the present invention; and

FIG. 2E shows cross-sectional views illustrative of the structure of the magnetic tunnel junction having a large pinned layer in accordance with the embodiment of the present invention.

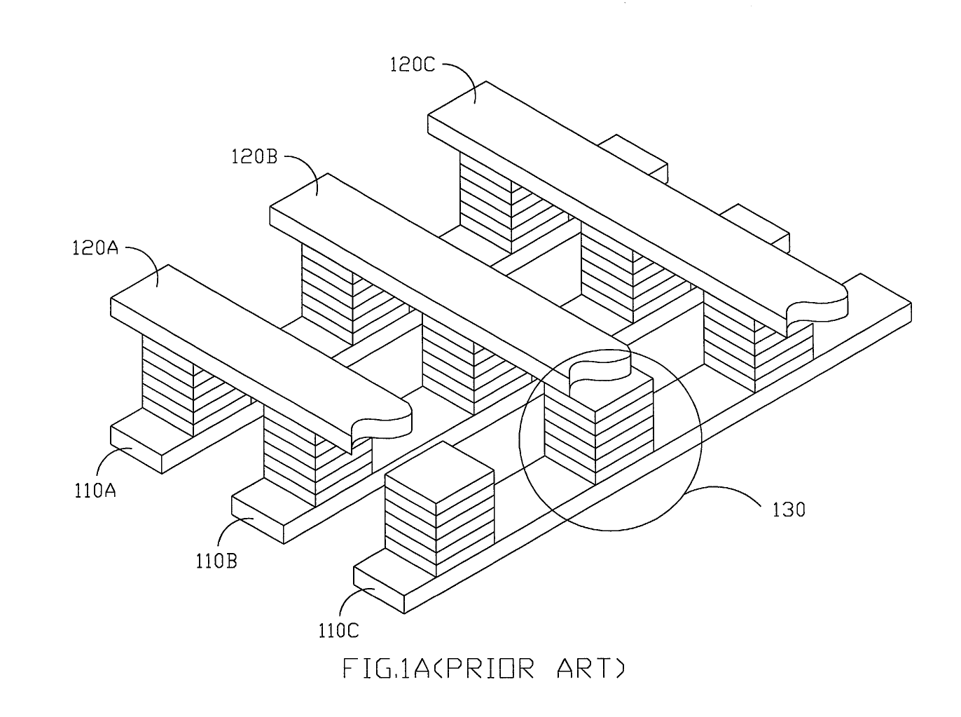

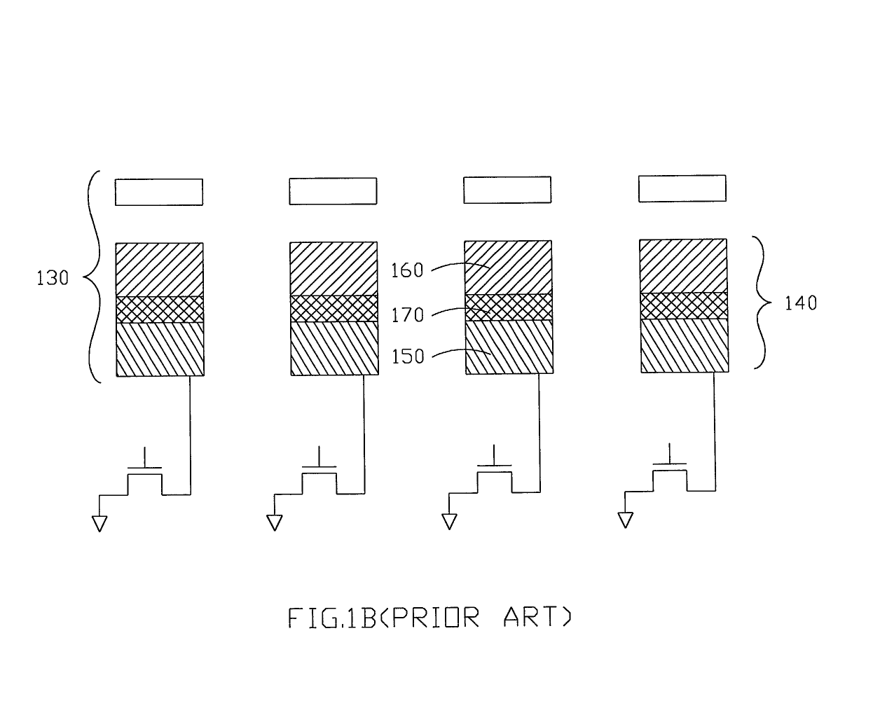

### DESCRIPTION OF THE PREFERRED EMBODIMENT

One preferred embodiment of the present invention will now be described in greater detail. Nevertheless, it should be recognized that the present invention can be practiced in a wide range of other embodiments besides those explicitly described, and the scope of the present invention is expressly not limited except as specified in the accompanying claims.

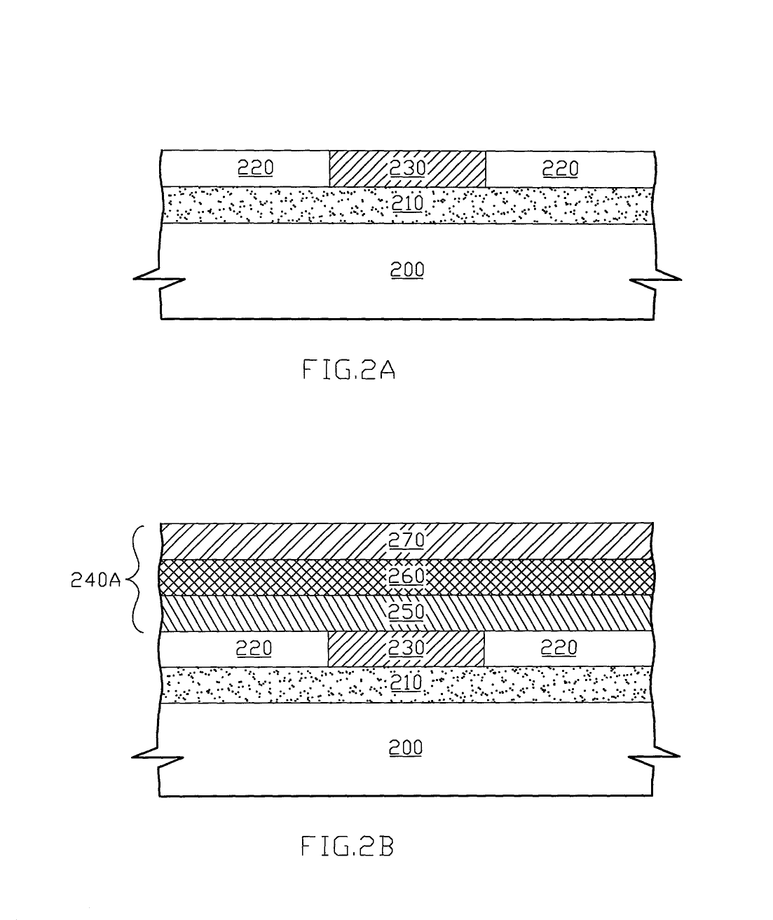

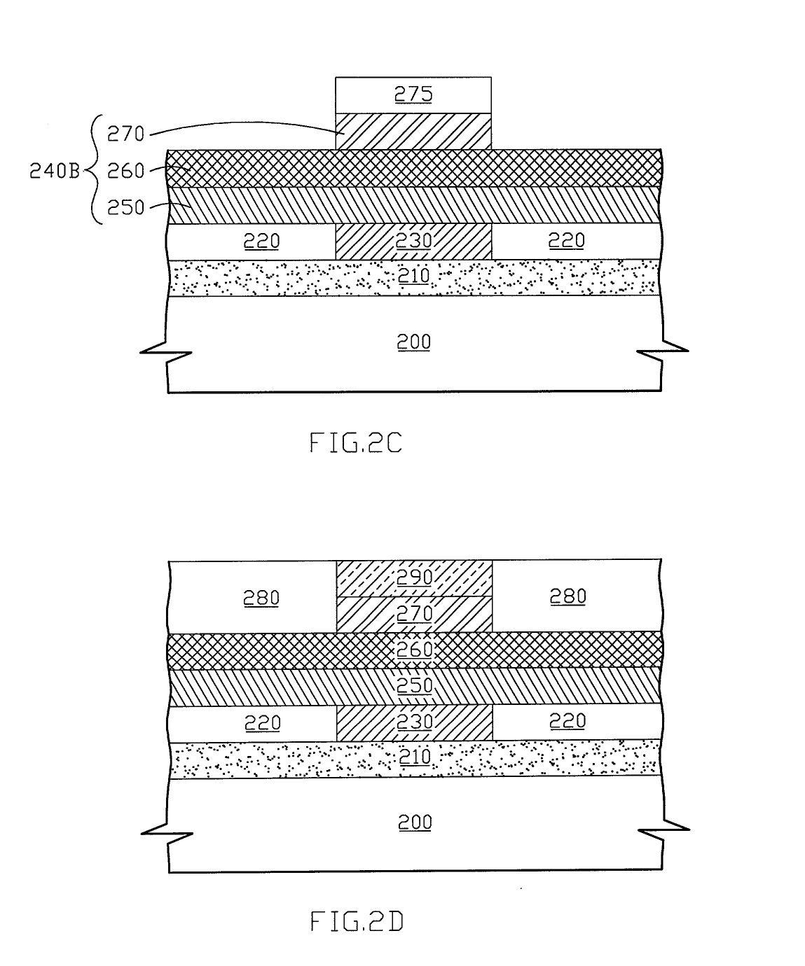

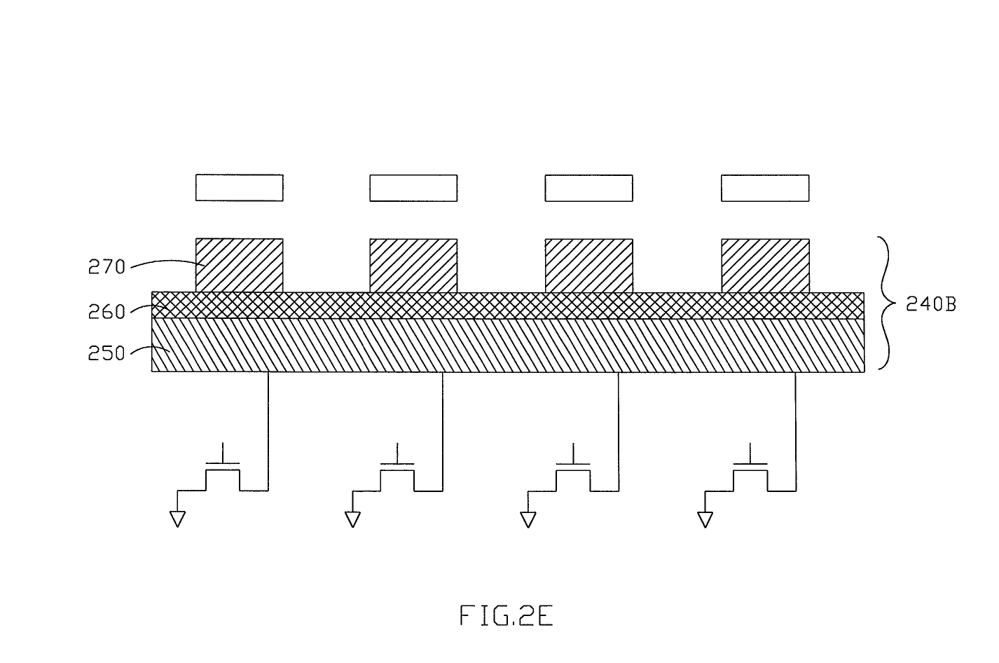

As illustrated in FIG. 2A, in an embodiment of the present invention, first of all, a semiconductor substrate 200 is provided. On the semiconductor substrate 200, a first conducting line layer 210, such as a word line, is formed and covered with a first insulating layer 220. Next, forming a contact hole in the first insulating layer 220 to expose a partial surface of the first conducting line layer 210. Afterward, forming a connected device 230, such as a diode, in the contact hole to connect with the first conducting line layer 210. Then the series of layers which make up the magnetic tunnel junction 240A are deposited by magnetron sputter deposition uniformly on the surface which is held near ambient temperature.

As illustrated in FIG. 2B, in this embodiment, in order, a pinned layer 250 having multi-layers that are magnetizable material, such as Ni, Co and Fe alloy, is deposited along the first insulating layer 220 and the connected device 230, wherein the direction of polarization of the pinned layer 250 is fixed. On top of the pinned layer 250, an insulating tunnel barrier layer 260 is formed, wherein the method for forming the insulating tunnel barrier layer 260 utilizes a material of Al that is deposited and oxidized to form a aluminum oxide layer, such as Al₂O₃. Then a free layer 270 having multi-layers that are magnetizable material, such as Ni, Co and Fe alloy, is deposited on the insulating tunnel barrier layer 260, wherein the direction of polarization of the free layer 270 is variable. There is a single large MTJ 240A that covers the entire surface of the first insulating layer 220 on the first conducting line layer 210.

As illustrated in FIG. 2C, in this embodiment, a photoresist layer 275 is formed and defined on the free layer 270. The large MTJ 230 is then patterned into a small MTJ 240B by way of using the the etching process and the photoresist layer 275 as an etching mask and through the free layer 270 to the surface of the insulating tunnel barrier layer 260. Next, the photoresist layer 275 is removed. Subsequently, the small MTJ 240B are then covered with a second insulating layer 280. Afterward, a contact hole is then formed in the second insulating layer 280 to the top of the small MTJ 240B. Finally, a second conducting line layer 290, such as bit line, is then formed on top of the structure to contact the free layer 260 in the small MTJ 240B, as shown in FIG. 2D.

In this embodiment of the present invention, as discussed above, this invention can form a novel structure of the magnetic tunnel junction to substitute for conventional structure, so as to obtain a good magnetiresistance performance. Hence, the present invention is appropriate for deep sub-micron technology to provide the semiconductor devices. Furthermore, the present invention can form pinned layer having a larger area in the magnetic tunnel junction, so as to avoid the stray field of the pinned layer edge and prevent the edge defect of the sandwich structure during the etching process, as shown in FIG. 2E. Moreover, this invention can get an etching stop layer by forming a larger area pinned layer to decrease the complex of process. On the other hand, the magnetic field of the present cell is easy to be determined due to the stronger signal from the resistance. Accordingly, this invention can provide a magnetoresistive random access memory which has a magnetiresistance performance is better than the conventional one, so as to increase yield and quality of the process and, hence, decrease cost. In other words, the present invention can correspond to economic effect.

Of course, it is possible to apply the present invention to the process for forming the magnetic tunnel junction, and also it is possible to the present invention to any one magnetoresistive random access memory devices in the semiconductor devices. Also, this invention can be applied to use the large pinned layer concerning the process of the magnetoresistive random access memory used for avoiding the edge defect and making the stronger signal from the resistance have not been developed at present. Method of the present invention is the best magnetoresistive random access memory compatible process for deep sub-micro process.

Obviously, many modifications and variations of the present invention are possible in light of the above teachings. It is therefore to be understood that within the scope of the appended claims, the present invention may be practiced otherwise than as specifically described herein.

Although specific embodiments have been illustrated and described, it will be obvious to those skilled in the art that various modifications may be made without departing from what is intended to be limited solely by the appended claims.

What is claimed is:

1. A method for forming a magnetic tunnel junction of a magnetoresistive random access memory, said method comprising:
providing a substrate;
forming a first magnetizable layer on said substrate;
forming an insulating tunnel barrier layer on said first magnetizable layer;
forming a second magnetizable layer on said insulating tunnel barrier layer;
forming and defining a photoresist layer on said second magnetizable layer;
etching said second magnetizable layer by said photoresist layer as an etching mask until said insulating tunnel barrier layer; and
removing said photoresist layer to form said magnetic tunnel junction.

2. The method according to claim 1, wherein said first magnetizable layer comprises a fixed direction of polarization.

3. The method according to claim 1, wherein the step for forming said first magnetizable layer comprises a deposition process.

4. The method according to claim 1, wherein said insulating tunnel barrier layer comprises an oxide layer.

5. The method according to claim 4, wherein said oxide layer comprises a aluminum oxide layer.

6. The method according to claim 1, wherein the step for forming said insulating tunnel barrier layer comprises a deposition process.

7. The method according to claim 1, wherein the step for forming said insulating tunnel barrier layer comprises an oxidation process.

8. The method according to claim 1, wherein said second magnetizable layer comprises a variable direction of polarization.

9. The method according to claim 1, wherein the step for forming said second magnetizable layer comprises a deposition process.

10. A method for forming a magnetic tunnel junction of a magnetoresistive random access memory, said method comprising:
providing a substrate;
forming a pinned layer on said substrate;
depositing and forming an aluminum layer on said pinned layer;
forming an aluminum oxide layer on said pinned layer by way of using an oxidation process to form an insulating tunnel barrier layer on said pinned layer;
forming a free layer on said insulating tunnel barrier layer;
forming and defining a photoresist layer on said free layer;
etching said free layer by said photoresist layer as an etching mask until said insulating tunnel barrier layer; and
removing said photoresist layer to form said magnetic tunnel junction.

11. The method according to claim 10, wherein said pinned layer comprises a magnetizable material.

12. The method according to claim 10, wherein the direction of polarization of said pinned layer is fixed.

13. The method according to claim 10, wherein the step for forming said pinned layer comprises a deposition process.

14. The method according to claim 10, wherein said free layer comprises a magnetizable material.

15. The method according to claim 10, wherein said free layer comprises a variable direction of polarization.

16. The method according to claim 10, wherein the step for forming said free layer comprises a deposition process.

17. A method for forming a magnetoresistive random access memory with a magnetic tunnel junction, said method comprising:
providing a substrate;
forming a first conducting line layer on said substrate and covering with a first insulating layer;
forming a first contact hole in said first insulating layer to expose a partial surface of said first conducting line layer;
forming a connected device in said first contact hole to connect said first conducting line layer;
forming a first magnetizable layer on said insulating layer and said connected device;
forming an insulating tunnel barrier layer on said first magnetizable layer;
forming a second magnetizable layer on said insulating tunnel barrier layer;
forming and defining a photoresist layer on said second magnetizable layer;
etching said second magnetizable layer by said photoresist layer as an etching mask until said insulating tunnel barrier layer;
removing said photoresist layer to form a magnetic tunnel junction;
forming a second insulating layer and covering said magnetic tunnel junction;
forming a second contact hole in said second insulating layer to expose the surface of said second magnetizable layer of said magnetic tunnel junction; and
forming a second conducting line layer in said second contact hole to contact said second magnetizable layer and form said magnetoresistive random access memory.

18. The method according to claim 17, wherein said first magnetizable layer comprises a fixed direction of polarization.

19. The method according to claim 17, wherein the step for forming said first magnetizable layer comprises a deposition process.

20. The method according to claim 17, wherein said insulating tunnel barrier layer comprises an oxide layer.

21. The method according to claim 20, wherein said oxide layer comprises a aluminum oxide layer.

22. The method according to claim 17, wherein the step for forming said insulating tunnel barrier layer comprises a deposition process.

23. The method according to claim 17, wherein the step for forming said insulating tunnel barrier layer comprises an oxidation process.

24. The method according to claim 17, wherein said second magnetizable layer comprises a variable direction of polarization.

25. The method according to claim 17, wherein the step for forming said second magnetizable layer comprises a deposition process.

26. A method for forming a magnetoresistive random access memory with a magnetic tunnel junction, said method comprising:
providing a substrate;
forming a word line layer on said substrate and covering with a first insulating layer;
forming a first contact hole in said first insulating layer to expose a partial surface of said word line layer;
forming a connected device in said first contact hole to connect said word line layer;
forming a pinned layer on said first insulating layer and said connected device;
depositing and forming an aluminum layer on said pinned layer;
forming an aluminum oxide layer on said pinned layer by way of using an oxidation process to form an insulating tunnel barrier layer on said pinned layer;
forming a free layer on said insulating tunnel barrier layer;
forming and defining a photoresist layer on said free layer;
etching said free layer by said photoresist layer as an etching mask until said insulating tunnel barrier layer;
removing said photoresist layer to form said magnetic tunnel junction;
forming a second insulating layer and covering said magnetic tunnel junction;
forming a second contact hole in said second insulating layer to expose the surface of said free layer of said magnetic tunnel junction; and
forming a bit line layer in said second contact hole to contact said free layer and form said magnetoresistive random access memory.

27. The method according to claim 26, wherein said pinned layer comprises a magnetizable material.

28. The method according to claim 26, wherein said pinned layer comprises a fixed direction of polarization.

29. The method according to claim 26, wherein the step for forming said pinned layer comprises a deposition process.

30. The method according to claim 26, wherein said free layer comprises a magnetizable material.

31. The method according to claim 26, wherein said free layer comprises a variable direction of polarization.

32. The method according to claim 26, wherein the step for forming said free layer comprises a deposition process.
